(19) United States
(12) Patent Application Publication
(10) Pub. No.: US 2016/0343977 A1
(43) Pub. Date: Nov. 24, 2016

(54) OLED PACKAGE STRUCTURE AND PACKAGE METHOD THEREOF

(71) Applicant: SHENZHEN CHINA STAR OPTOELECTRONICS TECHNOLOGY CO., LTD., Shenzhen, Guangdong (CN)

(72) Inventors: Weijing ZENG, Shenzhen, Guangdong (CN); Yifan WANG, Shenzhen, Guangdong (CN)

(73) Assignee: Shenzhen China Star Optoelectronics Technology Co., Ltd., Shenzhen, Guangdong (CN)

(21) Appl. No.: 14/424,930

(22) PCT Filed: Feb. 9, 2015
(86) PCT No.: PCT/CN2015/072485

§ 371 Date: Feb. 27, 2015

(30) Foreign Application Priority Data
Dec. 4, 2014 (CN) 201410734804.4

(51) Int. Cl. H01L 51/52; H01L 51/56

(52) U.S. Cl. CPC H01L 51/5246; H01L 51/5253; H01L 51/5259; H01L 51/56

(57) ABSTRACT

The present invention provides an OLED package structure and a package method thereof, and the structure comprises a package cover plate, a substrate, oppositely positioned with the package cover plate, an OLED element, positioned between the package cover plate and the substrate and set on the substrate, a metal oxide layer, formed on a surface of the OLED element, seal, positioned at periphery of the OLED element to bond the package cover plate and the substrate, dryer filler, filling an internal space surrounded by the seal between the package cover plate and the substrate, and covering the OLED element and frit glass, located at periphery of the seal to bond the package cover plate and the substrate, and the structure utilizes the seal and the frit glass to implement the package, and meanwhile, the dryer filler is filled inside the seal to make the package structure possess well tightness and mechanical strength, and a metal oxide layer is formed on a surface of the OLED element inside to prevent the issue of display uneven brightness caused by the corrosion of the dryer filler, particularly the liquid dryer to the lighting element.

### FIELD OF THE INVENTION

The present invention relates to a display skill field, and more particularly to an OLED package structure and a package method thereof.

### BACKGROUND OF THE INVENTION

OLED is an Organic Light Emitting Diodes Display possessing properties of self-illumination, high brightness, wide view angle, high contrast, flexibility and low power consumption, etc., and accordingly has been received more attentions. As being the display of next generation, it has been gradually replaced traditional liquid crystal displays and widely applied in cellular phone screens, computer displays, full color TV, etc. OLED display technology is different from the traditional liquid crystal display technology and the back light is not required. It utilizes an ultra thin organic material coating layer and a glass substrate, and theses organic material will illuminate when the current is conducted. Because the organic material can easily react with water and oxygen, the OLED display panel has extremely high demands for the package as being the display element based on the organic material.

The common package technologies today are: ultra-violet (UV) curing seal package, laser sealing package, face seal package, seal and dryer fill package (dam and fill), thin film package, etc. The ultra-violet (UV) light curing technology is the earliest and most common skill employed for the LCD/OLED packages. Nevertheless, the UV glue is organic material. The molecular clearance after curing becomes larger. The water vapor and the oxygen can easily pass through the media and reach to the inside of the sealed space. Therefore, the technology should be suitable for the application field which is not sensitive to the water vapor and the oxygen, such as LCD. The seal and the dryer filler are more suitable for the package of the large scale panels. The dryer fills up the entire panel. On one hand, it can prevent the OLED from the invasion of water and oxygen; on the other hand, the dryer is filled inside the package cover plate and the TFT substrate in a way of surface contact to form a mechanical unit of high strength, which is better than the panel of ultra-violet (UV) curing seal package with the same thickness as considering the loading of daily use. That is to say, under the certain allowable mechanical loading, the seal and the dryer filler package can be utilized to achieve the package of the large scale panels. Laser sealing package technology is a new type panel glass package skill under development now. In China, almost no related documents are published. It is to mix the glass powder to be a solution with a certain viscosity. The solution is coated on the package glass and heated to remove the solvent. Then, after the glasses to be package have been attached, the laser is activated to burn and melt the glass powder instantly. Ultimately, the two sheet glasses are attached and bonded together. The Laser sealing skill uses the inorganic package media, and thus the capability of resisting water vapor and oxygen is so strong. Therefore, it is suitable to the OLED technology, which is highly sensitive to the water vapor and oxygen. However, the laser sealing technology is not suitable for the large scale panels because the gaps exist in the panel, and the panel can be easily bent to influence the display effect and easily broken.

### SUMMARY OF THE INVENTION

An objective of the present invention is to provide an OLED package structure utilizing the seal and the frit glass to implement the package, and meanwhile, the dryer filler is filled inside the seal to make the package structure possess well tightness and mechanical strength, and a metal oxide layer is formed on a surface of the OLED element inside to prevent the issue of display uneven brightness caused by the corrosion of the dryer filler, particularly the liquid dryer to the lighting element.

Another objective of the present invention is to provide an OLED package method, as utilizing the seal and the frit glass to implement the package and meanwhile, combining the seal and dryer filler for package, to increase the bonding area of the package cover plate and the substrate for preventing bend or crush of the package structure, promote tightness and mechanical strength is raised in advance, and a metal oxide layer is formed on a surface of the OLED element inside to prevent the issue of display uneven brightness caused by the corrosion of the dryer filler, particularly the liquid dryer to the lighting element.

For realizing the aforesaid objectives, the present invention provides an OLED package structure, comprising a package cover plate, a substrate, oppositely positioned with the package cover plate, an OLED element, positioned between the package cover plate and the substrate and set on the substrate, seal, positioned at periphery of the OLED element to bond the package cover plate and the substrate, dryer filler, filling an internal space surrounded by the seal between the package cover plate and the substrate, and covering the OLED element and frit glass, located at periphery of the seal to bond the package cover plate and the substrate.

The OLED element further comprises a metal oxide layer formed on a surface of the OLED element.

Both the package cover plate and the substrate are glass substrates, and an indentation is formed on the package cover plate corresponding to a location of the OLED element, and an internal space of the indentation accommodates a dimension of the OLED element.

The seal is UV seal, and a gap between the seal and the frit glass is larger than or equal to 500 um.

The dryer filler is liquid dryer or curable dryer, and the liquid dryer is polymer containing aluminum.

The present invention provides an OLED package method, comprising steps of:

step 1, providing a package cover plate and a substrate.

locating an OLED element on the substrate, and an indentation is formed on the package cover plate corresponding to a location of the OLED element, and an internal space of the indentation accommodates a dimension of the OLED element;

step 2, deposing a metal oxide layer on a surface of the OLED element;

step 3, coating a circle of glass glue on the cover package plate on edges at open side of the indentation, and forming frit glass by high temperature presintering.

step 4, coating a glue frame on the package cover plate at an inner side of the frit glass and an outer side of the indentation;

step 5, coating dryer filler in an internal space on the package cover plate surrounded by the seal;

step 6, oppositely laminating the package cover plate and the substrate under a vacuum condition, and curing the seal by UV irradiation;

step 7, melting the frit glass by laser irradiation, and bonding the package cover plate and the substrate to accomplish the package of the package cover plate to the substrate.

In the step 2, ion bombardment is employed to implement surface treatment to a cathode of the OLED element to form the metal oxide layer.

In the step 3, screen print or dispensing is employed to coat the glass glue on the package cover plate.

In the step 4, the seal is UV seal, and a gap between the seal and the frit glass is larger than or equal to 500 um.

In the step 5, the dryer filler is liquid dryer or curable dryer, and the liquid dryer is polymer containing aluminum, and the dryer filler fills up the entire internal space surrounded by the seal between the package cover plate and the substrate.

The present invention further provides an OLED package structure, comprising a package cover plate, a substrate, oppositely positioned with the package cover plate, an OLED element, positioned between the package cover plate and the substrate and set on the substrate, seal, positioned at periphery of the OLED element to bond the package cover plate and the substrate, dryer filler, filling an internal space surrounded by the seal between the package cover plate and the substrate, and covering the OLED element and frit glass, located at periphery of the seal to bond the package cover plate and the substrate;

wherein the OLED element further comprises a metal oxide layer formed on a surface of the OLED element;

wherein both the package cover plate and the substrate are glass substrates, and an indentation is formed on the package cover plate corresponding to a location of the OLED element, and an internal space of the indentation accommodates a dimension of the OLED element.

The benefits of the present are: the OLED package structure of the present invention utilizes the seal and the frit glass to implement the package, and meanwhile, the dryer filler is filled inside the seal for possessing well tightness and mechanical strength, and a metal oxide layer is formed on a surface of the OLED element inside to prevent the issue of display uneven brightness caused by the corrosion of the dryer filler, particularly the liquid dryer to the lighting element. The OLED package method of the present invention, as utilizing the frit glass to implement the package and meanwhile, combining the seal and dryer filler for package, to increase the bonding area of the package cover plate and the substrate for preventing bend or crush of the package structure, promotes tightness and mechanical strength is raised in advance. Meanwhile, a metal oxide layer is formed on a surface of the OLED element inside to prevent the issue of display uneven brightness caused by the corrosion of the dryer filler, particularly the liquid dryer to the lighting element.

### BRIEF DESCRIPTION OF THE DRAWINGS

The technical solution and the beneficial effects of the present invention are best understood from the following detailed description with reference to the accompanying figures and embodiments.

In drawings,

FIG. 1 is a diagram of an OLED package structure according to the present invention;

FIG. 2 is a flowchart of an OLED package method according to the present invention;

FIG. 3 is a diagram of the step 1 according to the OLED package method of the present invention;

FIG. 4 is a diagram of the step 2 according to the OLED package method of the present invention;

FIG. 5 is a diagram of the step 3 according to the OLED package method of the present invention;

FIG. 6 is a diagram of the step 4 according to the OLED package method of the present invention;

FIG. 7 is a diagram of the step 5 according to the OLED package method of the present invention;

FIG. 8 is a diagram of the step 6 according to the OLED package method of the present invention;

FIG. 9 is a diagram of the step 7 according to the OLED package method of the present invention.

### DETAILED DESCRIPTION OF PREFERRED EMBODIMENTS

For better explaining the technical solution and the effect of the present invention, the present invention will be further described in detail with the accompanying drawings and the specific embodiments.

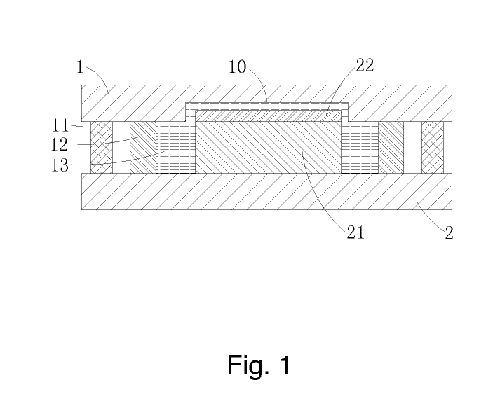

As shown in FIG. 1, the present invention provides an OLED package structure, comprising a package cover plate 1, a substrate 2, oppositely positioned with the package cover plate 1, an OLED element 21, positioned between the package cover plate 1 and the substrate 2 and set on the substrate 2, a metal oxide layer 22 formed on a surface of the OLED element 21, seal 12, positioned at periphery of the OLED element 21 to bond the package cover plate 1 and the substrate 2, dryer filler 13, filling an internal space surrounded by the seal 12 between the package cover plate 1 and the substrate 2, and covering the OLED element 21 and frit glass 11, located at periphery of the seal 12 to bond the package cover plate and 1 the substrate 2.

Preferably, both the package cover plate 1 and the substrate 2 are glass substrates.

Specifically, an indentation 10 is formed on the package cover plate 1 corresponding to a location of the OLED element 21, and an internal space of the indentation 10 accommodates a dimension of the OLED element 21.

The seal 12 is UV seal, and preferably, a gap between the seal 12 and the frit glass 11 is larger than or equal to 500 um.

The dryer filler 13 is liquid dryer or curable dryer, and preferably, the dryer filler 13 is liquid dryer, and the liquid dryer can be polymer containing aluminum, such as [R-O—Al═O]n(n≧1). The dryer filler 13 fills up the entire internal space surrounded by the seal 12 between the package cover plate 1 and the substrate 2 to achieve the effect for blocking water vapor.

In the aforesaid OLED package structure, the seal and the frit glass are utilized to implement the package, and meanwhile, the dryer filler is filled inside the seal for possessing well tightness and mechanical strength, and a metal oxide layer is formed on a surface of the OLED element inside to prevent the issue of display uneven brightness caused by the corrosion of the dryer filler, particularly the liquid dryer to the lighting element.

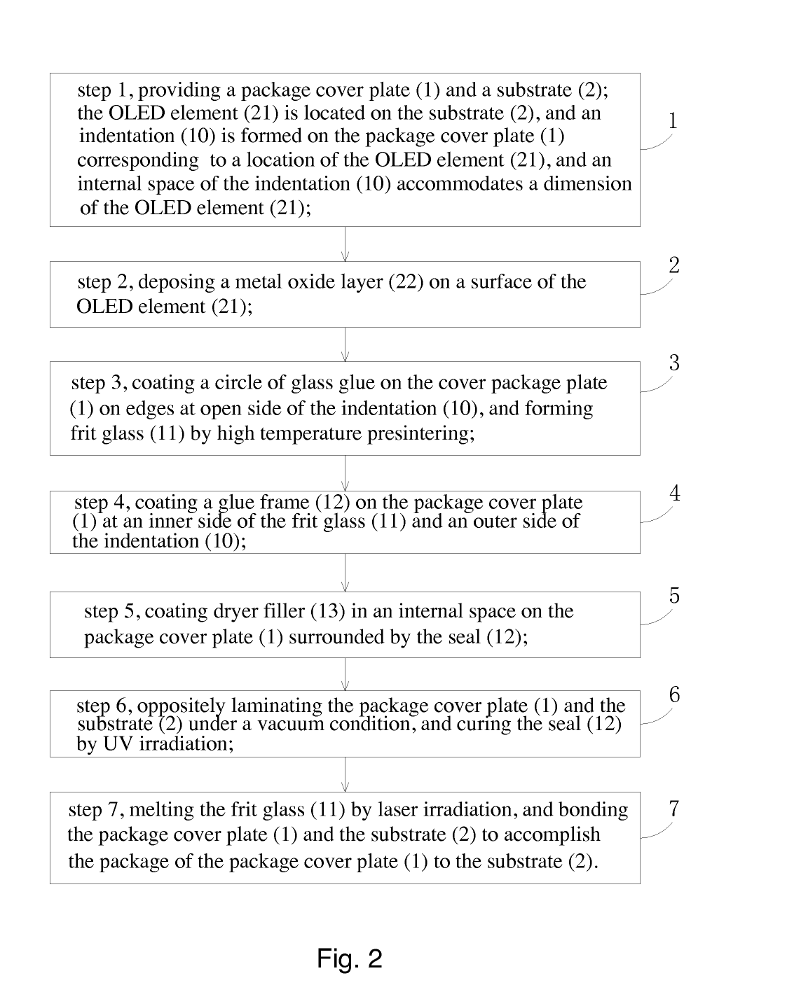

Please refer to FIG. 2. The present invention provides an OLED package method, comprising steps of:

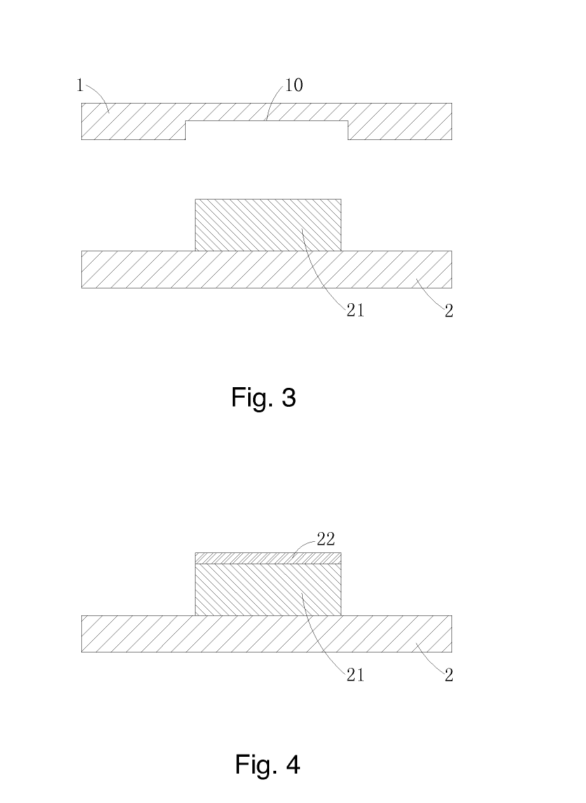

step 1, as shown in FIG. 3, providing a package cover plate 1 and a substrate 2;

Specifically, the OLED element 21 is located on the substrate 2, and an indentation 10 is formed on the package cover plate 1 corresponding to a location of the OLED element 21, and an internal space of the indentation 10 accommodates a dimension of the OLED element 21.

step 2, as shown in FIG. 4, deposing a metal oxide layer 22 on a surface of the OLED element 21.

Specifically, ion bombardment is employed to implement surface treatment to an cathode of the OLED element 21 to form the metal oxide layer 22. The metal oxide layer 22 is capable of effectively preventing the issue of display uneven brightness caused by the corrosion of the dryer filler, particularly the liquid dryer to the lighting element.

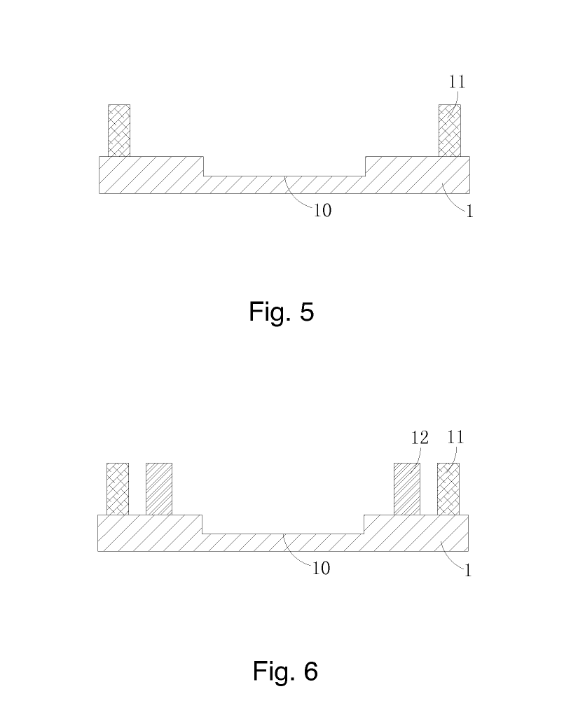

step 3, as shown in FIG. 5, coating a circle of glass glue on the cover package plate 1 on edges at open side of the indentation 10, and forming frit glass 11 by high temperature presintering.

Specifically, screen print or dispensing is employed to coat the glass glue on the package cover plate 1.

step 4, as shown in FIG. 6, coating a glue frame 12 on the package cover plate 1 at an inner side of the frit glass 11 and an outer side of the indentation 10.

The seal 12 is UV seal, and preferably, a gap between the seal 12 and the frit glass 11 is larger than or equal to 500 um.

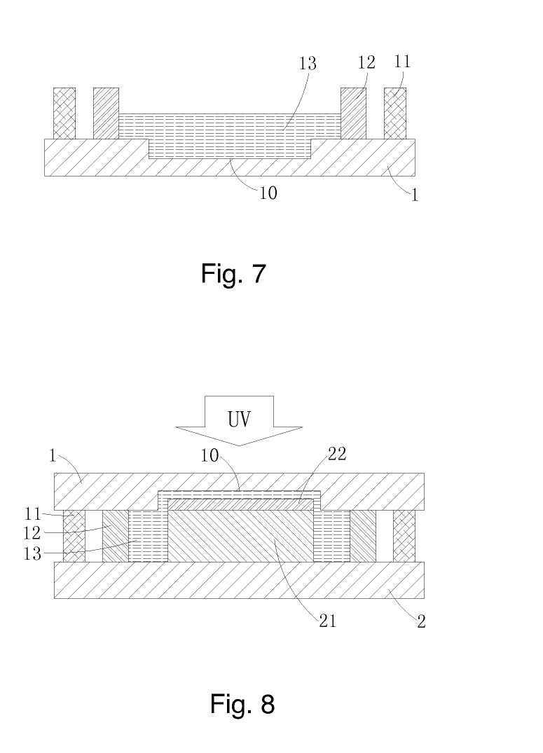

step 5, as shown in FIG. 7, coating dryer filler 13 in an internal space on the package cover plate 1 surrounded by the seal 12.

Specifically, the dryer filler 13 is liquid dryer or curable dryer, and preferably, the dryer filler 13 is liquid dryer, and the liquid dryer can be polymer containing aluminum, such as [R-O—Al═O]n(n≧1). The coating volume of the dryer filler 13 is controlled so that after the package cover plate 1 and the substrate 2 are laminated, the dryer filler 13 can fill up the entire internal space surrounded by the seal 12 between the package cover plate 1 and the substrate 2 to achieve the effect for blocking water vapor.

step 6, as shown in FIG. 8, oppositely laminating the package cover plate 1 and the substrate 2 under a vacuum condition, and curing the seal 12 by UV irradiation.

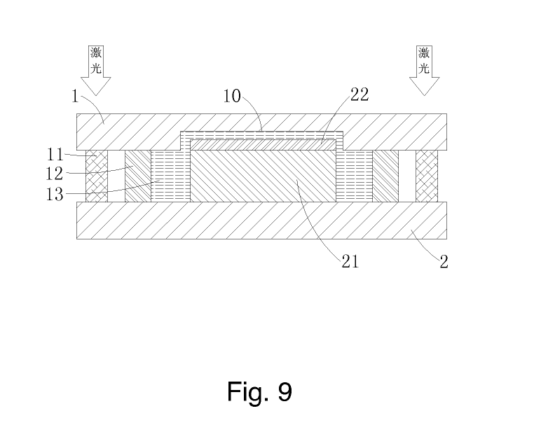

step 7, as shown in FIG. 9, melting the frit glass 11 by laser irradiation, and bonding the package cover plate 1 and the substrate 2 to accomplish the package of the package cover plate 1 to the substrate 2.

Specifically, the OLED structure after the package is accomplished is shown in FIG. 1.

In the aforesaid OLED package method, as utilizing the frit glass to implement the package and meanwhile, combining the seal and dryer filler for package, increases the bonding area of the package cover plate and the substrate to prevent bend or crush of the package structure for promoting tightness and raising mechanical strength in advance, and a metal oxide layer is formed on a surface of the OLED element inside to prevent the issue of display uneven brightness caused by the corrosion of the dryer filler, particularly the liquid dryer to the lighting element.

In conclusion, the OLED package structure of the present invention utilizes the seal and the frit glass to implement the package, and meanwhile, the dryer filler is filled inside the seal for possessing well tightness and mechanical strength, and a metal oxide layer is formed on a surface of the OLED element inside to prevent the issue of display uneven brightness caused by the corrosion of the dryer filler, particularly the liquid dryer to the lighting element. The OLED package method of the present invention, as utilizing the frit glass to implement the package and meanwhile, combining the seal and dryer filler for package, to increase the bonding area of the package cover plate and the substrate for preventing bend or crush of the package structure, promotes tightness and mechanical strength is raised in advance. Meanwhile, a metal oxide layer is formed on a surface of the OLED element inside to prevent the issue of display uneven brightness caused by the corrosion of the dryer filler, particularly the liquid dryer to the lighting element.

Above are only specific embodiments of the present invention, the scope of the present invention is not limited to this, and to any persons who are skilled in the art, change or replacement which is easily derived should be covered by the protected scope of the invention. Thus, the protected scope of the invention should go by the subject claims.

What is claimed is:

1. An OLED package structure, comprising a package cover plate, a substrate, oppositely positioned with the package cover plate, an OLED element, positioned between the package cover plate and the substrate and set on the substrate, seal, positioned at periphery of the OLED element to bond the package cover plate and the substrate, dryer filler, filling an internal space surrounded by the seal between the package cover plate and the substrate, and covering the OLED element and frit glass, located at periphery of the seal to bond the package cover plate and the substrate.

2. The OLED element according to claim 1, further comprising a metal oxide layer formed on a surface of the OLED element.

3. The OLED element according to claim 1, wherein both the package cover plate and the substrate are glass substrates, and an indentation is formed on the package cover plate corresponding to a location of the OLED element, and an internal space of the indentation accommodates a dimension of the OLED element.

4. The OLED element according to claim 1, wherein the seal is UV seal, and a gap between the seal and the frit glass is larger than or equal to 500 um.

5. The OLED element according to claim 1, wherein the dryer filler is liquid dryer or curable dryer, and the liquid dryer is polymer containing aluminum.

6. An OLED package method, comprising steps of:
step 1, providing a package cover plate and a substrate.
locating an OLED element on the substrate, and an indentation is formed on the package cover plate corresponding to a location of the OLED element, and an internal space of the indentation accommodates a dimension of the OLED element;
step 2, deposing a metal oxide layer on a surface of the OLED element;
step 3, coating a circle of glass glue on the cover package plate on edges at open side of the indentation, and forming frit glass by high temperature presintering.
step 4, coating a glue frame on the package cover plate at an inner side of the frit glass and an outer side of the indentation;
step 5, coating dryer filler in an internal space on the package cover plate surrounded by the seal;
step 6, oppositely laminating the package cover plate and the substrate under a vacuum condition, and curing the seal by UV irradiation;
step 7, melting the frit glass by laser irradiation, and bonding the package cover plate and the substrate to accomplish the package of the package cover plate to the substrate.

7. The OLED package method according to claim 6, wherein in the step 2, ion bombardment is employed to implement surface treatment to a cathode of the OLED element to form the metal oxide layer.

8. The OLED package method according to claim 6, wherein in the step 3, screen print or dispensing is employed to coat the glass glue on the package cover plate.

9. The OLED package method according to claim 6, wherein in the step 4, the seal is UV seal, and a gap between the seal and the frit glass is larger than or equal to 500 um.

10. The OLED package method according to claim 6, wherein in the step 5, the dryer filler is liquid dryer or curable dryer, and the liquid dryer is polymer containing aluminum, and the dryer filler fills up the entire internal space surrounded by the seal between the package cover plate and the substrate.

11. An OLED package structure, comprising a package cover plate, a substrate, oppositely positioned with the package cover plate, an OLED element, positioned between the package cover plate and the substrate and set on the substrate, seal, positioned at periphery of the OLED element to bond the package cover plate and the substrate, dryer filler, filling an internal space surrounded by the seal between the package cover plate and the substrate, and covering the OLED element and frit glass, located at periphery of the seal to bond the package cover plate and the substrate.
wherein the OLED element further comprises a metal oxide layer formed on a surface of the OLED element;
wherein both the package cover plate and the substrate are glass substrates, and an indentation is formed on the package cover plate corresponding to a location of the OLED element, and an internal space of the indentation accommodates a dimension of the OLED element.

12. The OLED element according to claim 11, wherein the seal is UV seal, and a gap between the seal and the frit glass is larger than or equal to 500 um.

13. The OLED element according to claim 11, wherein the dryer filler is liquid dryer or curable dryer, and the liquid dryer is polymer containing aluminum.
